(19) United States
(12) Patent Application Publication
(10) Pub. No.: US 2026/0038536 A1
(43) Pub. Date: Feb. 5, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Jinhyuck CHO, Suwon-si (KR); Jungsook KIM, Suwon-si (KR); Eunyeong PARK, Suwon-si (KR); Jong-Hyun PARK, Suwon-si (KR); Dong-Sik LEE, Suwon-si (KR); Sangjun HONG, Suwon-si (KR); Seungwan HONG, Suwon-si (KR)

(73) Assignee: Samsung Electronics Co., Ltd., Suwon-si (KR)

(21) Appl. No.: 19/089,127

(22) Filed: Mar. 25, 2025

(30) Foreign Application Priority Data
Aug. 5, 2024 (KR) 10-2024-0103922

(51) Int. Cl. G11C 5/06; H01L 23/00; H01L 25/18; H10B 43/10; H10B 43/27; H10B 43/35; H10B 43/40; H10B 80/00

(52) U.S. Cl. CPC G11C 5/06; H01L 24/08; H01L 25/18; H10B 43/10; H10B 43/27; H10B 43/35; H10B 43/40; H10B 80/00; H01L 24/32; H01L 24/48; H01L 2224/08145; H01L 2224/32145; H01L 2224/32225; H01L 2224/48147; H01L 2224/48227; H01L 2225/06524; H01L 2924/1438

(57) ABSTRACT

A semiconductor memory device may include a substrate including a cell array region and an extension region, a plurality of gate electrodes alternately stacked in a first direction on the substrate and in a staircase structure on the extension region, a channel structure penetrating through the plurality of gate electrodes on the cell array region and extending in the first direction, a through via penetrating through a first gate electrode of the plurality of gate electrodes and a second gate electrode of the plurality of gate electrodes, and the second gate electrode being between the first gate electrode and the substrate, the through via connecting to the first gate electrode, and an insulating pattern between the second gate electrode and the through via. The insulating pattern includes an insulating structure on a sidewall of the second gate electrode.

### CROSS-REFERENCE TO RELATED APPLICATION

This application claims priority to Korean Patent Application No. 10-2024-0103922, filed in the Korean Intellectual Property Office on Aug. 5, 2024, the entire contents of which are hereby incorporated by reference.

### BACKGROUND

Some example embodiments relate to a semiconductor memory device and an electronic system including the same.

In the semiconductor industry there is a desire for a semiconductor memory device capable of storing higher-capacity data in an electronic system utilizing data storage. Accordingly, ways to increase the data storage capacity of the semiconductor memory devices are being studied. For example, methods for increasing the data storage capacity of semiconductor devices have been proposed including a three-dimensional arrangement of memory cells instead of a two-dimensional arrangement of memory cells.

### SUMMARY

Some of the example embodiments of the present disclosure provide a semiconductor memory device with improved electrical characteristics and/or reliability.

Some example embodiments of the present disclosure also provide an electronic system with improved electrical characteristics and/or reliability.

According to some example embodiments of the present disclosure, the capping pattern is disposed between the insulating structure and the first through via and thus can insulate between the second gate electrode and the first through via. Accordingly, electrical characteristics and/or reliability of the semiconductor memory device can be improved.

According to some example embodiments of the present disclosure, a semiconductor memory device may include a substrate including a cell array region and an extension region, a plurality of gate electrodes alternately stacked in a first direction on the substrate and in a staircase structure on the extension region, a channel structure penetrating through the plurality of gate electrodes on the cell array region and extending in the first direction, a through via penetrating through a first gate electrode of the plurality of gate electrodes and a second gate electrode of the plurality of gate electrodes, and the second gate electrode being between the first gate electrode and the substrate, the through via connecting to the first gate electrode, and an insulating pattern between the second gate electrode and the through via. The insulating pattern includes an insulating structure on a sidewall of the second gate electrode, the insulating structure including a first insulating layer and a second insulating layer surrounding the first insulating layer, and the insulating structure in contact with upper and lower surfaces of the first insulating layer, and a capping pattern between the insulating structure and the through via.

According to some example embodiments of the present disclosure, a semiconductor memory device may include a substrate including a cell array region and an extension region, a mold structure including a plurality of gate electrodes and a plurality of mold insulating layers alternately stacked on a first side of the substrate in a first direction, the first direction being perpendicular to the first side of the substrate, the mold structure including the plurality of gate electrodes with a pad portion in a staircase structure on the extension region, a channel structure penetrating through the plurality of gate electrodes and extending on the cell array region in the first direction, a through via penetrating through a pad portion of a first gate electrode of the plurality of gate electrodes and a second gate electrode of the plurality of gate electrodes on the extension region, the second gate electrode being between the first gate electrode and the substrate, and the second gate electrode electrically connected to the pad portion of the first gate electrode, and an insulating pattern between the second gate electrode and the through via and surrounding a portion of a sidewall of the through via. The insulating pattern includes an insulating structure including a first insulating layer and a second insulating layer surrounding three surfaces of the first insulating layer, a capping pattern between the insulating structure and the through via, and the capping pattern covers a first side of the insulating structure defined by a side surface of the first insulating layer and a side surface of the second insulating layer.

According to some example embodiments of the present disclosure, an electronic system may include a main substrate, a semiconductor memory device on the main substrate, the semiconductor memory device including a peripheral circuit structure, and a cell structure stacked on the peripheral circuit structure, and a controller on the main substrate, the controller being electrically connected to the semiconductor memory device. The cell structure includes a substrate including a cell array region and an extension region, a plurality of gate electrodes alternately stacked on the substrate in a first direction, and in a staircase structure on the extension region, a channel structure penetrating through the plurality of gate electrodes on the cell array region and extending in the first direction, a through via penetrating through a first gate electrode of the plurality of gate electrodes and a second gate electrode of the plurality of gate electrodes, and the second gate electrode being between the first gate electrode and the substrate, the through via connecting to the first gate electrode, an insulating pattern between the second gate electrode and a sidewall of the through via, and the through via is penetrating through the substrate and connected to the peripheral circuit structure, and the insulating pattern includes an insulating structure on a sidewall of the second gate electrode, and the insulating structure including a first insulating layer and a second insulating layer, and the second insulating layer surrounding the first insulating layer and in contact with upper and lower surfaces of the first insulating layer, and a capping pattern between the insulating structure and the through via.

### BRIEF DESCRIPTION OF THE DRAWINGS

The above and other embodiments and features of the present disclosure will become more apparent by describing in detail example embodiments thereof with reference to the attached drawings, in which:

FIG. 1 is an example plan view provided to explain a semiconductor memory device according to some example embodiments;

FIG. 2 is a cross-sectional view taken along line A-A of FIG. 1;

FIG. 3 is a cross-sectional view taken along line B-B of FIG. 1;

FIG. 4 is an enlarged view provided to explain a region Q1 of FIG. 2;

FIG. 5 is an enlarged view provided to explain a region Q2 of FIG. 2;

FIG. 6 is a diagram provided to explain a semiconductor memory device according to some example embodiments;

FIG. 7 is a diagram provided to explain a semiconductor memory device;

FIG. 8 is a diagram provided to explain a semiconductor memory device according to some example embodiments;

FIG. 9 is a diagram provided to explain a semiconductor memory device according to some example embodiments;

FIGS. 10 and 11 are diagrams provided to explain a semiconductor memory device according to some example embodiments;

FIG. 12 is a diagram provided to explain a semiconductor memory device according to some example embodiments;

FIG. 13 is a diagram provided to explain a semiconductor memory device according to some example embodiments;

FIGS. 14 to 23 are diagrams illustrating intermediate stages, which are provided to explain a method for manufacturing a semiconductor memory device according to some example embodiments;

FIG. 24 is an example block diagram provided to explain an electronic system according to some example embodiments;

FIG. 25 is an example perspective view illustrating an electronic system including a semiconductor memory device according to some example embodiments;

FIG. 26 is a schematic cross-sectional view taken along line V-V of FIG. 25.

### DETAILED DESCRIPTION

Hereinafter, a semiconductor memory device and a method for manufacturing the same according to some example embodiments will be described in detail with reference to the drawings.

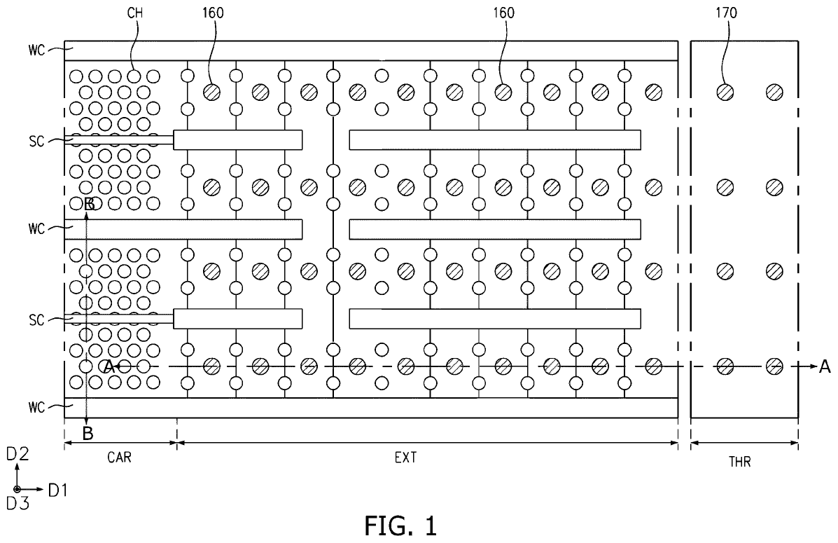

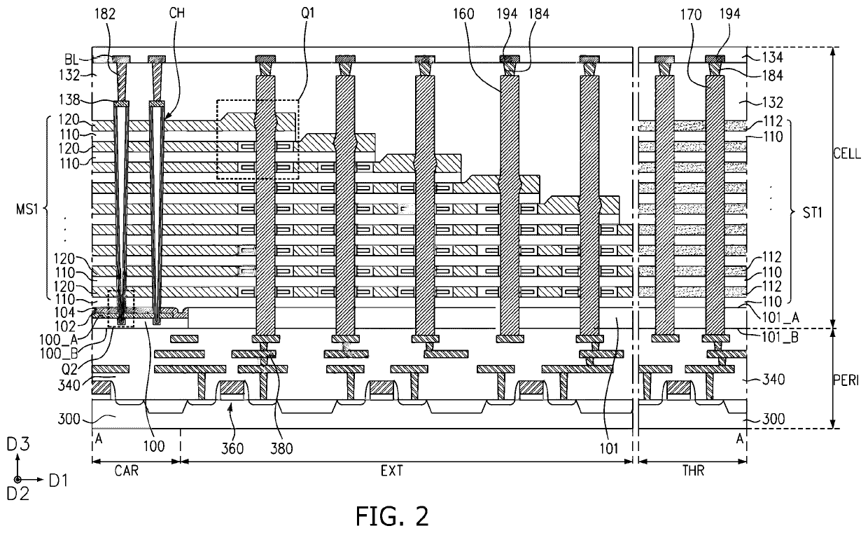

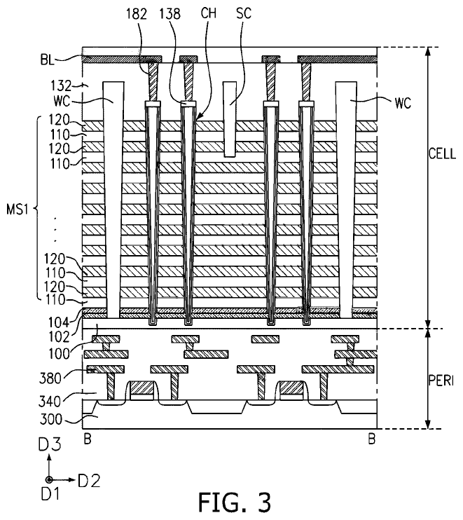

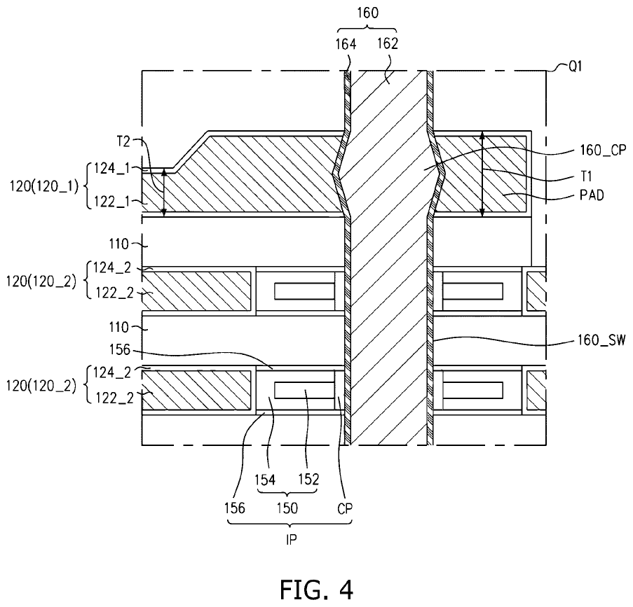

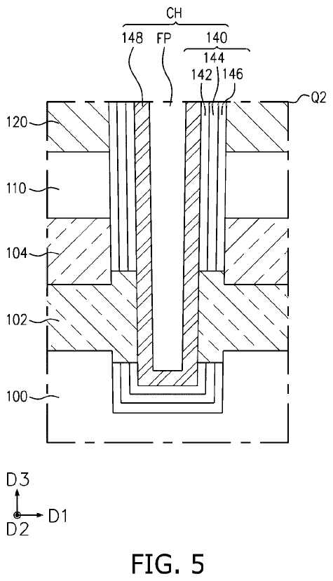

FIG. 1 is an example plan view provided to explain a semiconductor memory device according to some example embodiments. FIG. 2 is a cross-sectional view taken along line A-A of FIG. 1. FIG. 3 is a cross-sectional view taken along line B-B of FIG. 1. FIG. 4 is an enlarged view provided to explain a region Q1 of FIG. 2. FIG. 5 is an enlarged view provided to explain a region Q2 of FIG. 2.

Referring to FIGS. 1 to 5, the semiconductor memory device according to some example embodiments may include a cell structure CELL and a peripheral circuit structure PERI.

The cell structure CELL may include a cell substrate 100, an insulating substrate 101, a first mold structure MS1, an insulating pattern IP, a channel structure CH, a first through via 160, a second through via 170, a bit line BL, etc.

The substrate may include a cell array region CAR, an extension region EXT, and a through region THR. The substrate may include the cell substrate 100 and the insulating substrate 101. The cell substrate 100 may be provided on the cell array region CAR.

A memory cell array including a plurality of memory cells may be formed on the cell array region CAR. The extension region EXT may be disposed around the cell array region CAR. For example, the extension region EXT may surround the cell array region CAR. The through region THR may be disposed outside the extension region EXT. For example, the through region THR may be disposed on one side of the extension region EXT, but example embodiments are not limited thereto.

For example, the cell substrate 100 may include a semiconductor substrate such as a silicon substrate, a germanium substrate, or a silicon-germanium substrate. Alternatively, the cell substrate 100 may include a Silicon-On-Insulator (SOI) substrate, a Germanium-On-Insulator (GOI) substrate, etc. However, example embodiments are not limited thereto. In some example embodiments, the cell substrate 100 may include polysilicon (poly Si).

The cell substrate 100 may include a first side 100_A and a second side 100_B opposite the first side 100_A. The first side 100_A of the cell substrate 100 may be a surface on which the first mold structure MS1 and the channel structure CH are disposed. The first side 100_A of the cell substrate 100 may be referred to as a front side of the cell substrate 100. The second side 100_B of the cell substrate 100 may be referred to as a back side of the cell substrate 100.

The insulating substrate 101 may be provided on the extension region EXT and the through region THR. The insulating substrate 101 may include a first side 101_A and a second side 101_B opposite the first side 101_A. The first side 101_A of the insulating substrate 101 may be a surface on which the first mold structure MS1 and a first stack ST1 are disposed. The first side 101_A of the insulating substrate 101 may be referred to as a front side of the insulating substrate 101. The second side 101_B of the insulating substrate 101 may be referred to as a back side of the insulating substrate 101.

For example, the insulating substrate 101 may include at least one of silicon oxide, silicon nitride, silicon oxynitride, and silicon carbide, but example embodiments are not limited thereto.

Although it is illustrated that the second side 101_B of the insulating substrate 101 is disposed on the same plane as the second side 100_B of the cell substrate 100, this is only an example. As another example, the second side 101_B of the insulating substrate 101 may be lower than the second side 100_B of the cell substrate 100.

The first mold structure MS1 may be formed on the first side 100_A of the cell substrate 100. The first mold structure MS1 may include a plurality of mold insulating layers 110 and a plurality of gate electrodes 120 alternately stacked in a third direction D3. Each of the mold insulating layers 110 and each of the gate electrodes 120 may have a layered structure extending parallel to the first side 100_A of the cell substrate 100. The gate electrodes 120 may be spaced apart from each other by the mold insulating layers 110 and stacked in order on the cell substrate 100.

In some example embodiments, some of the gate electrodes 120 of the plurality of gate electrodes 120 may be used as a ground select line GSL and an erase control line ECL of the semiconductor memory device. For example, the gate electrodes 120 of the plurality of gate electrodes 120, which are adjacent to source structures 102 and 104, may be used as the erase control line ECL. The erase control line ECL may be used as a gate electrode of an erase transistor. The erase transistor may generate a Gate Induced Drain Leakage (GIDL) to perform an erase operation on a plurality of memory cell transistors. A gate electrode 120 adjacent to the erase control line ECL may be provided as a ground select line GSL. However, example embodiments are not limited thereto. The arrangement and number of the ground select lines GSL may vary.

In some example embodiments, some of the plurality of gate electrodes 120 may be provided as a string select line SSL of the semiconductor memory device. For example, the gate electrodes 120 of the plurality of gate electrodes 120, which are adjacent to the bit line BL, may be provided as the string select line SSL. However, example embodiments are not limited thereto. The arrangement and number of string select lines SL may vary.

The mold insulating layer 110 may include an insulating material. For example, the mold insulating layer 110 may include at least one of silicon oxide, silicon nitride, and silicon oxynitride, but example embodiments are not limited thereto.

The plurality of mold insulating layers 110 and the plurality of gate electrodes 120 may be stacked in a staircase pattern on the extension region EXT. For example, one end of the plurality of mold insulating layers 110 and one end of the plurality of gate electrodes 120 in a staircase structure may be disposed on the extension region EXT. The plurality of gate electrodes 120 may extend to different lengths in a first direction D1 and a second direction D2 to have a step difference. In some example embodiments, the plurality of gate electrodes 120 may include a pad portion PAD disposed in a staircase structure.

The first through via 160 may be disposed on the extension region EXT. The first through via 160 may be penetrating through the first mold structure MS1 and the insulating substrate 101 to be electrically connected to the peripheral circuit structure PERI. The first through via 160 may be connected to a first gate electrode 120_1 of the plurality of gate electrodes 120.

The first through via 160 may include a conductive pillar 162 and a barrier conductive film 164. The conductive pillar 162 may extend in the third direction D3. The barrier conductive film 164 may be disposed on a side surface of the conductive pillar 162. The barrier conductive film 164 may surround the conductive pillar 162.

The conductive pillar 162 and the barrier conductive film 164 may include a conductive material. For example, the conductive pillar 162 may include a metal such as tungsten, nickel, cobalt, and tantalum, a metal silicide such as tungsten silicide, nickel silicide, cobalt silicide, tantalum silicide, doped polysilicon, or a combination thereof. However, example embodiments are not limited thereto. For example, the barrier conductive film 164 may include titanium nitride, tantalum nitride, tungsten nitride, or a combination thereof.

The plurality of gate electrodes 120 may include the first gate electrode 120_1 and a second gate electrode 120_2. The first gate electrode 120_1 may be electrically connected to the first through via 160. For example, the first through via 160 may be penetrating through the pad portion PAD of the first gate electrode 120_1. The first through via 160 may be connected to the pad portion PAD of the first gate electrode 120_1. The pad portion PAD of the first gate electrode 120_1 may surround the first through via 160. The pad portion PAD of the first gate electrode 120_1 may be in contact with the barrier conductive film 164.

The first gate electrode 120_1 may include a first filling conductive layer 122_1 and a first liner dielectric layer 124_1. The first filling conductive layer 122_1 may extend in the first direction D1. The first liner dielectric layer 124_1 may surround the first filling conductive layer 122_1. The first liner dielectric layer 124_1 may not be disposed between the pad portion PAD of the first gate electrode 120_1 and the first through via 160.

In some example embodiments, a thickness T1 of the pad portion PAD of the first gate electrode 120_1 may be greater than a thickness T2 of the plate of the first gate electrode 120_1. The thickness may refer to a thickness in the third direction D3.

In some example embodiments, the first through via 160 may include a connection portion 160_CP. The connection portion 160_CP of the first through via 160 may protrude toward the first gate electrode 120_1. The connection portion 160_CP of the first through via 160 may overlap with the pad portion PAD of the first gate electrode 120_1 in the first direction D1. The first liner dielectric layer 124_1 may not be disposed on the connection portion 160_CP of the first through via 160. In other words, the connection portion 160_CP of the first through via 160 may be in contact with the first filling conductive layer 122_1.

The first through via 160 may be penetrating through the second gate electrode 120_2. The second gate electrode 120_2 may be kept from being electrically connected to the first through via 160 by the insulating pattern IP. The second gate electrode 120_2 may be the gate electrode 120 of the plurality of gate electrodes 120, which is disposed between the substrates 100 and 101 and the first gate electrode 120_1.

The second gate electrode 120_2 may include a second filling conductive layer 122_2 and a second liner dielectric layer 124_2. The second filling conductive layer 122_2 may extend in the first direction D1. The second liner dielectric layer 124_2 may surround the second filling conductive layer 122_2.

The filling conductive layers 122_1 and 122_2 may include a conductive material. For example, the filling conductive layers 122_1 and 122_2 may include a metal such as tungsten, cobalt, and nickel, or a semiconductor material such as silicon, but example embodiments are not limited thereto.

The liner dielectric layers 124_1 and 124_2 may include silicon oxide, silicon nitride, or a metal oxide having a higher dielectric constant than silicon oxide. The metal oxide may include a hafnium oxide, an aluminum oxide, a zirconium oxide, a tantalum oxide, or a combination thereof.

The insulating pattern IP may be disposed between the second gate electrode 120_2 and the first through via 160. The insulating pattern IP may be disposed on a sidewall 160_SW of the first through via 160. The insulating pattern IP may have a shape of a ring surrounding a portion of the sidewall 160_SW of the first through via 160. The insulating pattern IP may overlap with the second gate electrode 120_2 in the first direction D1. The second gate electrode 120_2 may be spaced apart from the first through via 160 by the insulating pattern IP.

The insulating pattern IP may include an insulating structure 150, a capping pattern CP, and a liner insulating layer 156.

The insulating structure 150 may include a first insulating layer 152 and a second insulating layer 154. The insulating structure 150 may be disposed on a sidewall of the second gate electrode 120_2. A first side of the insulating structure 150 may be in contact with the second gate electrode 120_2. A second side of the insulating structure 150 may be in contact with the capping pattern CP. The second side of the insulating structure 150 may be defined by a side surface of the first insulating layer 152 and a side surface of the second insulating layer 154. When viewed in a cross section, the first side and the second side of the insulating structure 150 may face each other in the first direction D1.

The second insulating layer 154 may surround the first insulating layer 152. For example, the second insulating layer 154 may surround three surfaces of the first insulating layer 152. The second insulating layer 154 may be in contact with the first insulating layer 152. For example, the second insulating layer 154 may be in contact with an upper surface, a lower surface, and a side surface of the first insulating layer 152. The second insulating layer 154 may expose at least one surface of the first insulating layer 152. The exposed surface of the first insulating layer 152 may be a surface facing one side surface of the first insulating layer 152 in contact with the second insulating layer 154 in the second direction D2.

The capping pattern CP may be disposed between the insulating structure 150 and the first through via 160. The capping pattern CP may be disposed on the sidewall 160_SW of the first through via 160. The capping pattern CP may be in contact with the first through via 160. The capping pattern CP may be disposed on the second side of the insulating structure 150. The capping pattern CP may cover the second side of the insulating structure 150. The capping pattern CP may be in contact with each of the first insulating layer 152 and the second insulating layer 154.

The liner insulating layer 156 may be disposed on the insulating structure 150 and the capping pattern CP. The liner insulating layer 156 may be disposed between the mold insulating layer 110 disposed on the second gate electrode 120_2 and the insulating structure 150 and between the mold insulating layer 110 disposed on the second gate electrode 120_2 and the capping pattern CP. The liner insulating layer 156 may extend in the first direction D1 along an upper surface of the insulating structure 150 and an upper surface of the capping pattern CP. The liner insulating layer 156 may extend in the first direction along a lower surface of the insulating structure 150 and a lower surface of the capping pattern CP. The liner insulating layer 156 may not be disposed between the second gate electrode 120_2 and the second insulating layer 154.

The first insulating layer 152 and the second insulating layer 154 may include an insulating material. The insulating material of the first insulating layer 152 and the insulating material of the second insulating layer 154 may each have a different etch selectivity. In some example embodiments, the first insulating layer 152 may include any one of silicon nitride and silicon oxynitride, and the second insulating layer 154 may include silicon oxide. However, example embodiments are not limited thereto.

The liner insulating layer 156 may include an insulating material. For example, the liner insulating layer 156 may include silicon oxynitride or silicon nitride. However, example embodiments are not limited thereto. The capping pattern CP may include an insulating material. For example, the capping pattern CP may include silicon oxynitride or silicon nitride.

The channel structure CH may be penetrating through the first mold structure MS1. For example, the channel structure CH may be penetrating through and intersect each of the plurality of mold insulating layers 110 and the plurality of gate electrodes 120. The channel structure CH may be disposed in a first channel hole extending in the third direction D3. The channel structure CH may have a pillar shape (e.g., a cylindrical shape) extending in the third direction D3. In some example embodiments, the cross section of the channel structure CH may have an inclined side surface such that the width of the channel structure CH is progressively narrowed toward the cell substrate 100. However, example embodiments are not limited thereto.

The channel structure CH may include an information storage film 140, a semiconductor pattern 148, and a filling pattern FP.

The semiconductor pattern 148 may extend in the third direction D3 through the first mold structure MS1. Although it is illustrated that the semiconductor pattern 148 has a cup shape, example embodiments are not limited thereto. For example, the semiconductor pattern 148 may have various shapes such as a cylindrical shape, a rectangular cylindrical shape, a filled pillar shape, etc. For example, the semiconductor pattern 148 may include a semiconductor material such as a single crystal silicon, a polycrystalline silicon, an organic semiconductor material, a carbon nanostructure, etc., although example embodiments are not limited thereto.

The information storage film 140 may be interposed between the semiconductor pattern 148 and each of the gate electrodes 120. For example, the information storage film 140 may extend along an outer surface of the semiconductor pattern 148. For example, the information storage film 140 may include at least one of silicon oxide, silicon nitride, silicon oxynitride, and a high-k material having a higher dielectric constant than the silicon oxide. However, example embodiments are not limited thereto. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some example embodiments, the channel structures CH may be disposed in a zigzag form. For example, as illustrated in FIG. 1, the channel structures CH may be disposed to cross each other in first and second directions D1 and D2. The channel structures CH disposed in the zigzag form may further improve the integration density of the semiconductor memory device. In some example embodiments, the channel structures CH may be arranged in a honeycomb form.

In some example embodiments, the information storage film 140 may include multiple films. The information storage film 140 may include a tunnel insulating film 142, a charge storage film 144, and a blocking insulating film 146, which may be stacked in order on the outer surface of the semiconductor pattern 148.

For example, the tunnel insulating film 142 may include the silicon oxide or a high-k material (e.g., aluminum oxide (Al₂O₃), hafnium oxide (HfO₂)) having a higher dielectric constant than the silicon oxide. For example, the charge storage film 144 may include silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

In some example embodiments, the channel structure CH may further include a filling pattern FP. The filling pattern FP may be formed to fill the inside of the cup-shaped semiconductor pattern 148. For example, the filling pattern FP may include an insulating material such as silicon oxide, but example embodiments are not limited thereto.

A channel pad 138 may be disposed on the channel structure CH. The channel pad 138 may be disposed on the channel structure CH and electrically connected to the semiconductor pattern 148. For example, the channel pad 138 may include polysilicon doped with an impurity, but example embodiments are not limited thereto. However, example embodiments are not limited thereto.

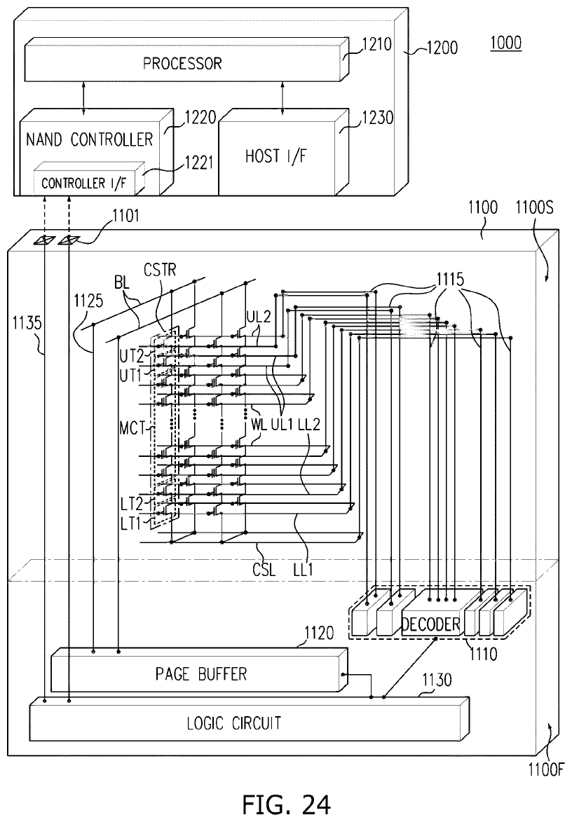

In some example embodiments, the source structures 102 and 104 may be formed on the cell substrate 100. The source structures 102 and 104 may be disposed between the cell substrate 100 and the first mold structure MS1. For example, the source structures 102 and 104 may extend along the first side 100_A of the cell substrate 100. The source structures 102 and 104 may be formed such that they are connected to the semiconductor pattern 148 and/or the information storage film 140 of the channel structure CH. The source structures 102 and 104 may be used as a common source line (e.g., CSL of FIG. 24) of the semiconductor memory device. For example, the source structures 102 and 104 may include polysilicon or metal doped with an impurity, but example embodiments are not limited thereto.

In some example embodiments, the channel structure CH may be penetrating through the source structures 102 and 104. For example, a lower portion of the channel structure CH may be penetrating through the source structures 102 and 104 and disposed in the cell substrate 100.

In some example embodiments, the source structure 102 and 104 may include multiple films. For example, the source structures 102 and 104 may include a first source layer 102 and a second source layer 104, which are sequentially stacked on the cell substrate 100. Each of the first source layer 102 and the second source layer 104 may include polysilicon doped with an impurity or polysilicon undoped with an impurity, but example embodiments are not limited thereto. The first source layer 102 may be in contact with the semiconductor pattern 148 and provided as a common source line (e.g., CSL of FIG. 24) of the semiconductor memory device. The second source layer 104 may be used as a support layer for limiting and/or preventing the mold stack from collapsing or falling in a replacement process for forming the first source layer 102.

Although not illustrated, a base insulating film may be interposed between the cell substrate 100 and the source structures 102 and 104. For example, the base insulating film may include at least one of silicon oxide, silicon nitride, and silicon oxynitride, but example embodiments are not limited thereto.

In some example embodiments, the source structures 102 and 104 may not be disposed in the extension region EXT where the insulating substrate 101 is formed. Although it is illustrated that the first side 101_A of the insulating substrate 101 is disposed on the same plane as upper surfaces of the source structures 102 and 104, example embodiments are not limited thereto. As another example, the first side 101_A of the insulating substrate 101 may be disposed at a higher level than the upper surfaces of the source structures 102 and 104.

A block isolation pattern WC may extend in the first direction D1 to cut the first mold structure MS1. At least a portion of the block isolation pattern WC may completely cut through the first mold structure MS1. At least a portion of the block isolation pattern WC may partially cut the first mold structure MS1.

A string isolation structure SC may extend in the first direction D1 to cut some of the gate electrodes 120. For example, the string isolation structure SC formed in a cell block may cut the string select line. The divided string select lines may independently control each region.

The block isolation pattern WC and the string isolation structure SC may include an insulating material, for example, at least one of silicon oxide, silicon nitride, and silicon oxynitride, but example embodiments are not limited thereto.

The bit line BL may be formed on the first mold structure MS1. The bit line BL may extend in the second direction D2 and intersect the block isolation pattern WC. In addition, the bit line BL may extend in the second direction D2 and be connected to the plurality of channel structures CH arranged along the second direction D2. For example, a bit line contact 182 connected to an upper portion of each of the channel structures CH may be formed in an interlayer insulating film 132. The bit line BL may be electrically connected to the channel structures CH through the bit line contact 182.

In some example embodiments, the first stack ST1 may be stacked on the insulating substrate 101 in the through region THR. The first stack ST1 may include a plurality of mold sacrificial films 112 and the plurality of mold insulating layers 110, which are alternately stacked on the insulating substrate 101. Each of the mold sacrificial films 112 and each of the mold insulating layers 110 may have a layered structure extending parallel to an upper surface of the insulating substrate 101. The mold sacrificial films 112 may be spaced apart from each other by the mold insulating layers 110 and sequentially stacked on the insulating substrate 101.

For example, the mold sacrificial film 112 may include an insulating material, for example, at least one of silicon oxide, silicon nitride, and silicon oxynitride, but example embodiments are not limited thereto. In some example embodiments, the mold sacrificial film 112 may include a material having etch selectivity with respect to the mold insulating layer 110. For example, the mold insulating layers 110 may include silicon oxide, and the mold sacrificial films 112 may include silicon nitride.

The interlayer insulating film 132 may be formed on the cell substrate 100 to cover the first mold structure MS1. The interlayer insulating film 132 may be formed on the insulating substrate 101 to cover the first stack ST1. For example, the interlayer insulating film 132 may include at least one of silicon oxide, silicon oxynitride, and a low-k material having a lower dielectric constant than silicon oxide, but example embodiments are not limited thereto.

The second through via 170 may be disposed in the through region THR. For example, the second through via 170 may be penetrating through the first stack ST1 in the through region THR and may extend in the third direction D3. The second through via 170 may be penetrating through the insulating substrate 101 to be electrically connected to the peripheral circuit structure PERI.

Each of the first through via 160 and the second through via 170 may be connected to an upper wiring structure 194 on the interlayer insulating film 132. For example, a wiring insulating film 134 may be formed on the interlayer insulating film 132. The upper wiring structure 194 may be formed in the wiring insulating film 134. Each of the first through via 160 and the second through via 170 may be connected to the upper wiring structure 194 through a wiring contact 184. Although not illustrated in detail, the upper wiring structure 194 may be connected to the bit line BL. The upper wiring structure 194 and the wiring contact 184 may include a conductive material. For example, the upper wiring structure 194 and the wiring contact 184 may include tungsten (W) or copper (Cu), but example embodiments are not limited thereto.

The peripheral circuit structure PERI may include a peripheral circuit substrate 300, a peripheral circuit element 360, and a peripheral circuit wiring structure 380.

The peripheral circuit substrate 300 may be disposed under the cell substrate 100 and the insulating substrate 101. For example, an upper surface of the peripheral circuit substrate 300 may face the second side 100_B of the cell substrate 100. For example, the peripheral circuit substrate 300 may include a semiconductor substrate such as a silicon substrate, a germanium substrate, or a silicon-germanium substrate. Alternatively, the peripheral circuit substrate 300 may include a silicon-on-insulator (SOI) substrate, a germanium-on-insulator (GOI) substrate, etc.

The peripheral circuit element 360 may be formed on the peripheral circuit substrate 300. The peripheral circuit element 360 may configure a peripheral circuit that controls the operation of the semiconductor memory device. For example, the peripheral circuit element 360 may include a logic circuit 1130, a page buffer 1120, a decoder circuit 1110, etc. of FIG. 24. In the following description, a surface of the peripheral circuit substrate 300 with the peripheral circuit element 360 disposed thereon may be referred to as a front side of the peripheral circuit substrate 300. Conversely, a surface of the peripheral circuit substrate 300 opposite to the front side of the peripheral circuit substrate 300 may be referred to as a back side of the peripheral circuit substrate 300.

For example, the peripheral circuit element 360 may include a transistor, but example embodiments are not limited thereto. For example, the peripheral circuit element 360 may include not only various active elements such as transistors, etc., but also various passive elements such as capacitors, resistors, inductors, etc.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed in the peripheral wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and example embodiments are not limited thereto.

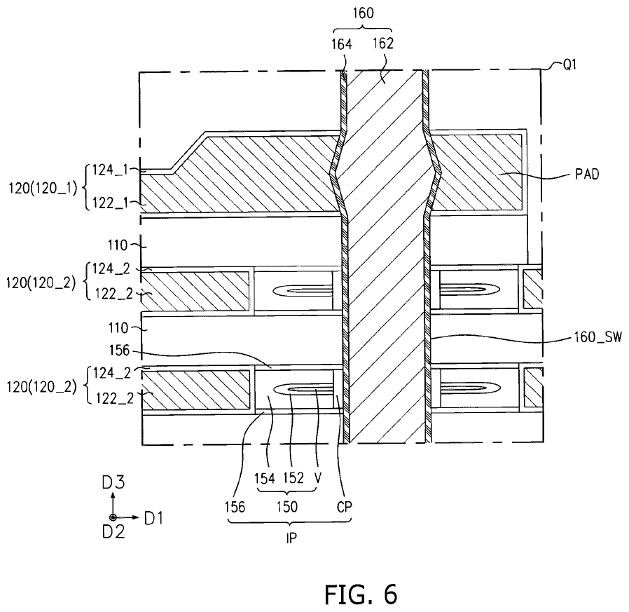

FIG. 6 is a diagram provided to explain a semiconductor memory device according to some example embodiments. For convenience of description, different configurations from those already described above in FIGS. 1 to 5 will be mainly described.

Referring to FIGS. 6 to 8, in the semiconductor memory device according to some example embodiments, the insulating structure 150 may further include a void V.

The void V may be formed in the first insulating layer 152. The first insulating layer 152 and the capping pattern CP may surround the void V. For example, the first insulating layer 152 may surround a portion of the void V, and the capping pattern CP may surround the rest of the void V. That is, the first insulating layer 152 and the capping pattern CP may completely surround the void V. The capping pattern CP may reduce and/or prevent other materials from being deposited inside the void V. The void V may refer to an empty space. In some example embodiments, the void V may be referred to as a seam or an air gap.

The side surface of the first insulating layer 152 may include a curved surface. The side surface of the first insulating layer 152, in particular, the side surface in contact with the second insulating layer 154 may have a shape convex toward the second insulating layer 154.

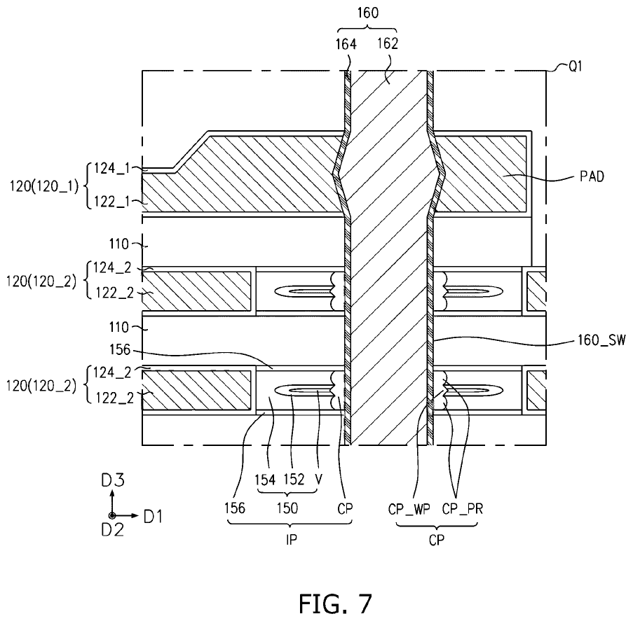

FIG. 7 is a diagram provided to explain a semiconductor memory device. For convenience of description, different configurations from those described in FIGS. 1 to 6 will be mainly described.

Referring to FIG. 7, in the semiconductor memory device according to some example embodiments, the capping pattern CP may include a protrusion portion CP_PR and a wedge pattern CP_WP.

The capping pattern CP may be in contact with the first insulating layer 152 and the second insulating layer 154, respectively. The protrusion portion CP_PR of the capping pattern CP may be in contact with the second insulating layer 154. The protrusion portion CP_PR of the capping pattern CP may protrude toward the second insulating layer 154. The protrusion portion CP_PR of the capping pattern CP may include a convex curved surface. The protrusion portion CP_PR of the capping pattern CP may be disposed on the liner insulating layer 156. The protrusion portion CP_PR of the capping pattern CP may include two protrusion portions CP_PR.

The wedge pattern CP_WP of the capping pattern CP may be in contact with the first insulating layer 152. A portion of the wedge pattern CP_WP of the capping pattern CP may be disposed in the void V. The wedge pattern CP_WP of the capping pattern CP may protrude toward the first insulating layer 152. The wedge pattern CP_WP of the capping pattern CP may be disposed between the protrusion portions CP_PR of the capping pattern CP.

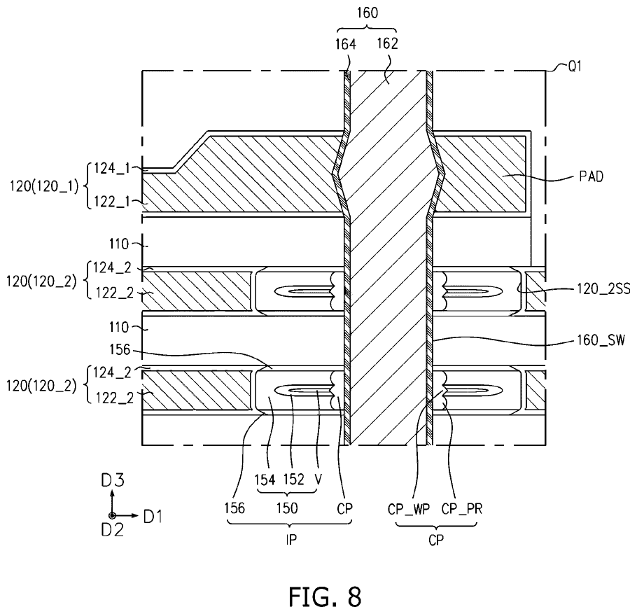

FIG. 8 is a diagram provided to explain a semiconductor memory device according to some example embodiments. For convenience of description, different configurations from those described in FIGS. 1 to 8 will be mainly described.

Referring to FIG. 8, in the semiconductor memory device according to some example embodiments, a side surface 120_2SS of the second gate electrode 120_2 may have a concave shape.

The side surface 120_2SS of the second gate electrode 120_2 may be in contact with the second insulating layer 154 and the liner insulating layer 156. The side surface 120_2SS of the second gate electrode 120_2 may include a concave curved surface. For example, the side surface 120_2SS of the second gate electrode 120_2 may be indented in a direction away from the first through via 160.

The second insulating layer 154 and the liner insulating layer 156 may form a convex curved surface corresponding to the side surface 120_2SS of the second gate electrode 120_2. In other words, a portion of the second insulating layer 154 and a portion of the liner insulating layer 156 may overlap the second gate electrode 120_2 in the third direction D3.

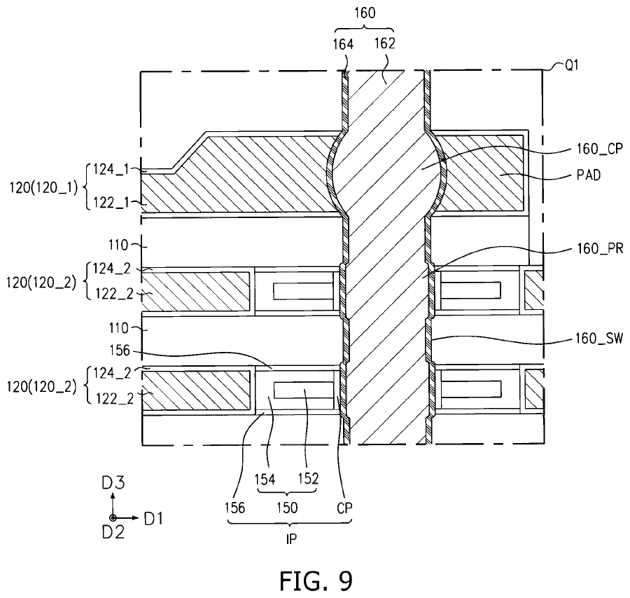

FIG. 9 is a diagram provided to explain a semiconductor memory device according to some example embodiments. For convenience of description, different configurations from those already described above in FIGS. 1 to 5 will be mainly described.

Referring to FIG. 9, in the semiconductor memory device according to some example embodiments, the first through via 160 may include the connection portion 160_CP and a protrusion portion 160_PR. Each of the connection portion 160_CP and the protrusion portion 160_PR of the first through via 160 may protrude outward from the sidewall 160_SW of the first through via 160.

The connection portion 160_CP of the first through via 160 may protrude toward the first gate electrode 120_1. The connection portion 160_CP of the first through via 160 may include a convex curved surface. The connection portion 160_CP of the first through via 160 may overlap with the pad portion PAD of the first gate electrode 120_1 in the first direction D1. The first liner dielectric layer 124_1 may not be disposed on the connection portion 160_CP of the first through via 160. In other words, the connection portion 160_CP of the first through via 160 may be in contact with the first filling conductive layer 122_1.

The protrusion portion 160_PR of the first through via 160 may be disposed on the insulating pattern IP. The protrusion portion 160_PR of the first through via 160 may protrude toward the insulating pattern IP. The protrusion portion 160_PR of the first through via 160 may overlap with the insulating pattern IP and the second gate electrode 120_2 in the first direction D1. A degree of protrusion of the protrusion portion 160_PR of the first through via 160 may be less than a degree of protrusion of the connection portion 160_CP of the first through via 160.

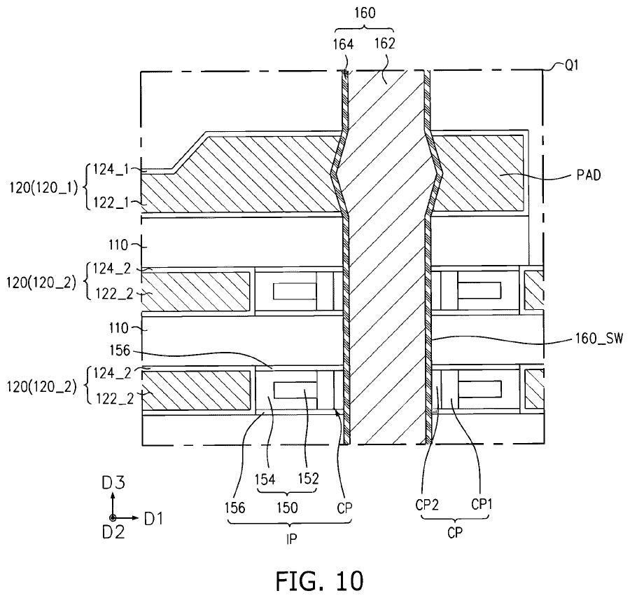

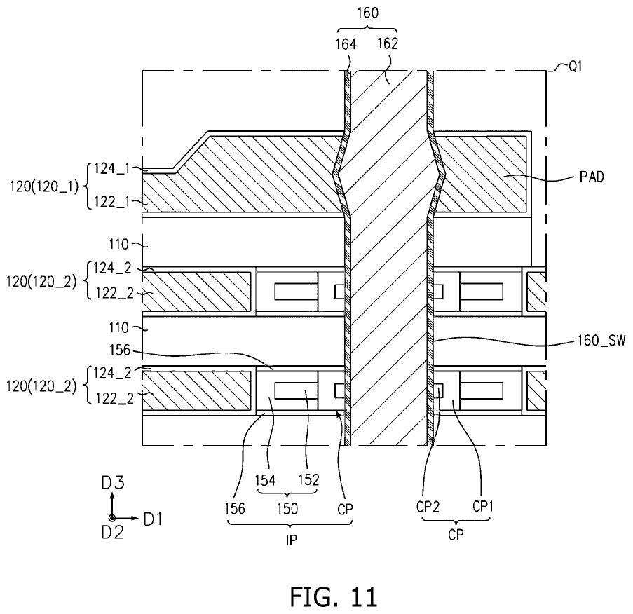

FIGS. 10 and 11 are diagrams provided to explain a semiconductor memory device according to some example embodiments. For convenience of description, different configurations from those already described above in FIGS. 1 to 5 will be mainly described.

Referring to FIGS. 10 and 11, in the semiconductor memory device according to some example embodiments, the capping pattern CP may include a first capping layer CP1 and a second capping layer CP2.

The capping pattern CP may be disposed between the insulating structure 150 and the first through via 160. The first capping layer CP1 may be disposed on the insulating structure 150. The first capping layer CP1 may be in contact with each of the first insulating layer 152 and the second insulating layer 154. The second capping layer CP2 may be disposed on the sidewall 160_SW of the first through via 160. The second capping layer CP2 may be disposed between the first capping layer CP1 and the first through via 160.

As shown in FIG. 10, in some example embodiments, the first capping layer CP1 may be spaced apart from the first through via 160 by the second capping layer CP2. The first capping layer CP1 may not be in contact with the first through via 160. In other words, the second capping layer CP2 may completely cover the sidewall 160_SW of the sidewalls 160_SW of the first through via 160, which is disposed between the liner insulating layers 156.

As shown in FIG. 11, in some example embodiments, the first capping layer CP1 may surround the second capping layer CP2. Each of the first capping layer CP1 and the second capping layer CP2 may be in contact with the first through via 160. In other words, the first capping layer CP1 and the second capping layer CP2 may be disposed on the sidewall 160_SW disposed between the liner insulating layers 156 of the sidewalls 160_SW of the first through via 160.

In some example embodiments, the first capping layer CP1 and the second capping layer CP2 may include different materials. For example, the first capping layer CP1 may include silicon oxide, and the second capping layer CP2 may include silicon nitride or silicon oxynitride. However, example embodiments are not limited thereto.

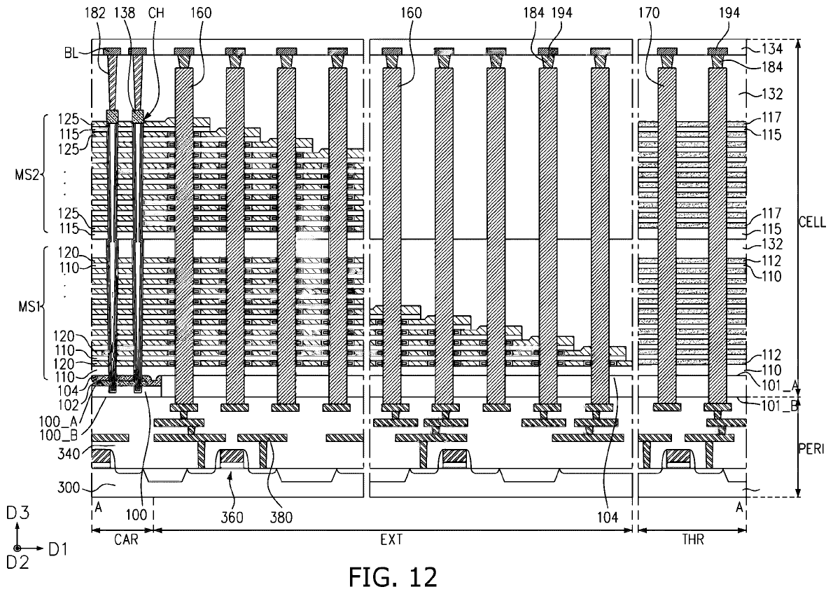

FIG. 12 is a diagram provided to explain a semiconductor memory device according to some example embodiments. For convenience of description, different configurations from those already described above in FIGS. 1 to 5 will be mainly described.

Referring to FIG. 12, in the semiconductor memory device according to some example embodiments, a second mold structure MS2 and the first mold structure MS1 may be stacked in order on the cell substrate 100 and the insulating substrate 101.

The second mold structure MS2 may be disposed on the first mold structure MS1. The second mold structure MS2 may include a plurality of mold insulating layers 115 and a plurality of gate electrodes 125 alternately stacked in the third direction D3. Each of the mold insulating layers 115 and each of the gate electrodes 125 may have a layered structure extending parallel to the first side 100_A of the cell substrate 100.

The channel structure CH may extend in the third direction D3 and may be penetrating through the first mold structure MS1 and the second mold structure MS2. The channel structure CH may have a bent portion between the first mold structure MS1 and the second mold structure MS2.

Although FIG. 12 illustrates that the number of mold structures MS1 and MS2 is two, example embodiments are not limited thereto. For example, the number of mold structures MS1 and MS2 may be three or four or more.

In the through region THR, the first stack ST1 and a second stack ST2 may be stacked in order on the insulating substrate 101. The second stack ST2 may be stacked on the first stack ST1. The second stack ST2 may include the plurality of mold insulating layers 115 and a plurality of mold sacrificial films 117, which are alternately stacked on the first stack ST1. The second through via 170 may be penetrating through the first stack ST1 and the second stack ST2 and extend in the third direction D3.

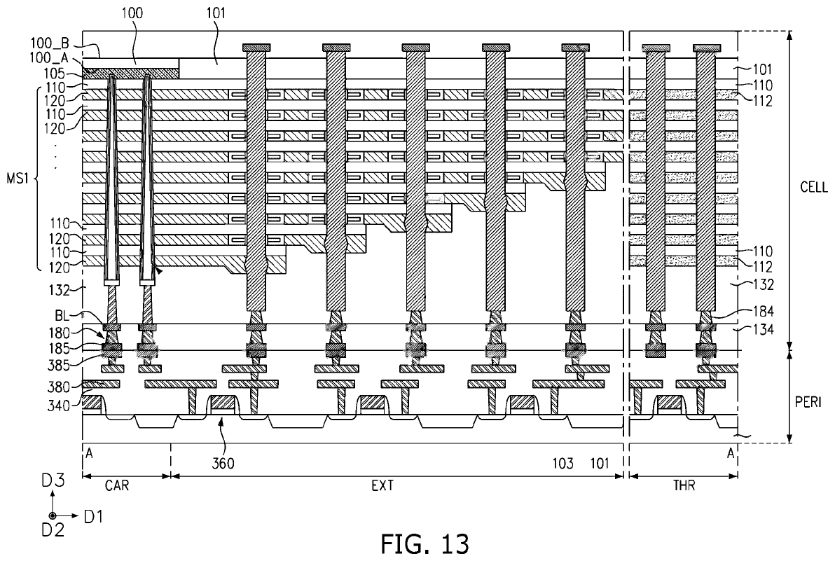

FIG. 13 is a diagram provided to explain a semiconductor memory device according to some example embodiments. For convenience of description, different configurations from those described in FIGS. 1 to 5 will be mainly described.

Referring to FIG. 13, the semiconductor memory device according to some example embodiments may include a common source plate 105.

The common source plate 105 may be disposed on the first side 100_A of the cell substrate 100. The common source plate 105 may be connected to the channel structure CH. For example, the common source plate 105 may be electrically connected to the semiconductor pattern of the channel structure CH. The common source plate 105 may be used as a common source line (e.g., CSL of FIG. 24) of the semiconductor memory device. The first mold structure MS1 may be disposed on the common source plate 105. For example, the common source plate 105 may include polycrystalline silicon or metal doped with an impurity, but example embodiments are not limited thereto.

The semiconductor memory device according to some example embodiments may have a chip-to-chip (C2C) structure. The C2C structure refers to manufacturing an upper chip including the memory cell structure (CELL) on a first wafer (e.g., the cell substrate 100), manufacturing a lower chip including the peripheral circuit structure (PERI) on a second wafer (e.g., the peripheral circuit substrate 300) that is different from the first wafer, and connecting the upper and lower chips to each other by a bonding method.

In some example embodiments, by the bonding method, it may mean a method of electrically connecting a first bonding metal 185 formed on the uppermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu—Cu bonding method. However, this is only an example, and it goes without saying that the first bonding metal 185 and the second bonding metal 385 may be formed of various other metals such as aluminum (Al), tungsten (W), etc. However, example embodiments are not limited thereto.

As the first bonding metal 185 and the second bonding metal 385 are bonded to each other, a bonding wiring structure 180 may be connected to the peripheral circuit wiring structure 380. Accordingly, the bit line BL and each of the gate electrodes 120 may be electrically connected to the peripheral circuit element 360.

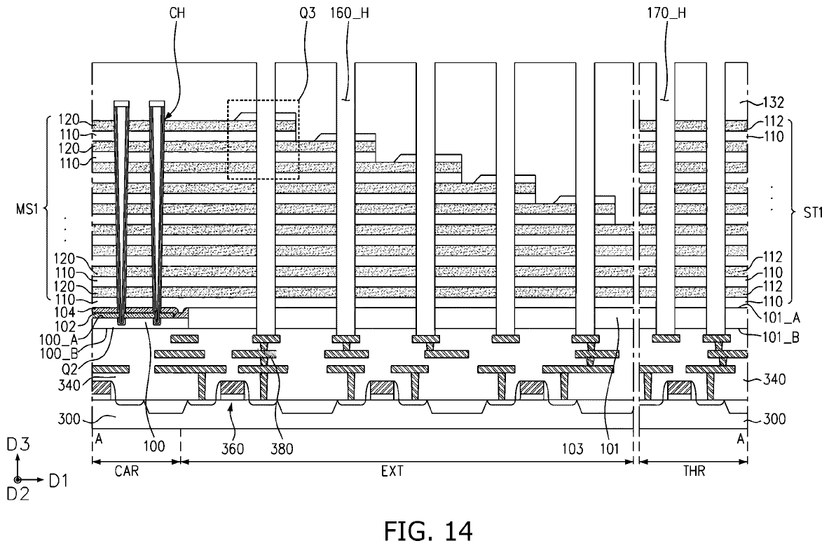

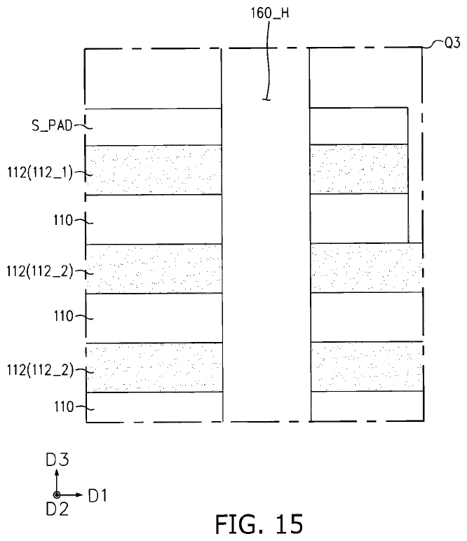

FIGS. 14 to 23 are diagrams illustrating intermediate stages, which are provided to explain a method for manufacturing a semiconductor memory device according to some example embodiments. FIG. 14 may correspond to a cross-sectional view taken along line A-A of FIG. 1. FIGS. 15 to 23 are enlarged views provided to explain a region Q3 of FIG. 14.

Referring to FIGS. 14 and 15, a pre-mold structure PMS1 and the first stack ST1 may be formed on the cell substrate 100 and the insulating substrate 101, and a first through via hole 160_H and a second through via hole 170_H may be formed.

In detail, the cell substrate 100 and the insulating substrate 101 may be stacked on the peripheral circuit structure PERI. The peripheral circuit structure PERI may include, on the peripheral circuit substrate 300, the peripheral circuit element 360, the peripheral circuit wiring structure 380, and a peripheral circuit inter-wire insulating film 340. The cell substrate 100 and the insulating substrate 101 may be stacked on the peripheral circuit inter-wire insulating film 340.

The pre-mold structure PMS1 may include the plurality of first mold insulating layers 110 and the plurality of first mold sacrificial films 112, which are alternately stacked on the first side 100_A of the cell substrate 100 and the first side 101_A of the insulating substrate 101. The pre-mold structure PMS1 may be patterned in a staircase structure on the extension region EXT. Accordingly, a portion of a first mold sacrificial film 112 of the pre-mold structure PMS1 may be exposed. A pad sacrificial film S_PAD may be formed on the exposed first mold sacrificial film 112.

For example, the pad sacrificial film S_PAD may be formed on a select mold sacrificial film 112_1 of the first mold sacrificial films 112. In some example embodiments, the pad sacrificial film S_PAD may be formed by forming an insulating layer (e.g., a silicon nitride layer) covering an exposed upper surface and side surface of the first mold sacrificial film 112, and removing a portion of the insulating layer such that the insulating layer only remains on the exposed upper surface of the first mold sacrificial film 112. A thickness of the pad sacrificial film S_PAD may be about 20% to about 110% of a thickness of the first mold sacrificial film 112, but example embodiments are not limited thereto. An unselect mold sacrificial film 112_2 may be the first mold sacrificial film 112 of the plurality of first mold sacrificial films 112, which is disposed between the select mold sacrificial film 112_1 and the insulating substrate 101.

The first stack ST1 may include the plurality of first mold insulating layers 110 and the plurality of first mold sacrificial films 112, which are alternately stacked on the first side 101_A of the insulating substrate 101. The first mold sacrificial film 112 may include a material having etch selectivity with respect to the first mold insulating layer 110. For example, the first mold insulating layer 110 may include a silicon oxide film, and the first mold sacrificial film 112 may include a silicon nitride film. However, example embodiments are not limited thereto.

The first through via hole 160_H may be penetrating through the pre-mold structure PMS1. The first through via hole 160_H may extend in the third direction D3 through the pad sacrificial film S_PAD, the first mold insulating layer 110, the first mold sacrificial film 112, and the insulating substrate 101. A bottom surface of the first through via hole 160_H may expose the peripheral circuit wiring structure 380 of the peripheral circuit structure PERI.

In addition, the second through via hole 170_H may be penetrating through the first stack ST1. The second through via hole 170_H may extend in the third direction D3 through the first stack ST1 and the insulating substrate 101. A bottom surface of the second through via hole 170_H may expose the peripheral circuit wiring structure 380 of the peripheral circuit structure PERI.

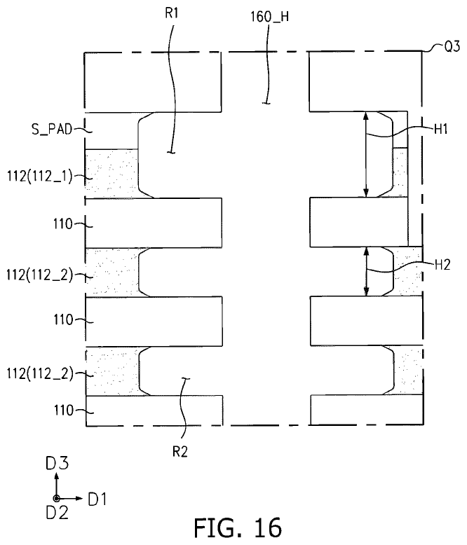

Referring to FIG. 16, a first recess R1 and a second recess R2 may be formed in the mold sacrificial film 112 and the pad sacrificial film S_PAD.

Specifically, the first recess R1 may be formed in the select mold sacrificial film 112_1 and the pad sacrificial film S_PAD, and the second recess R2 may be formed in the unselect mold sacrificial film 112_2. The first recess R1 and the second recess R2 may be formed by the same process. In some example embodiments, the process of forming the first recess R1 and the second recess R2 may include a wet etching process using phosphoric acid, but example embodiments are not limited thereto.

Since the first recess R1 is formed by removing the select mold sacrificial film 112_1 and the pad sacrificial film S_PAD, a height H1 of the first recess R1 may be greater than a height H2 of the second recess R2. The height as used herein may refer to a height in the third direction D3. Although it is illustrated that a depth of the first recess R1 in the first direction D1 is the same as a depth of the second recess R2 in the first direction D1, example embodiments are not limited thereto. For example, the depth of the first recess R1 in the first direction D1 may be greater than the depth of the second recess R2 in the first direction D1.

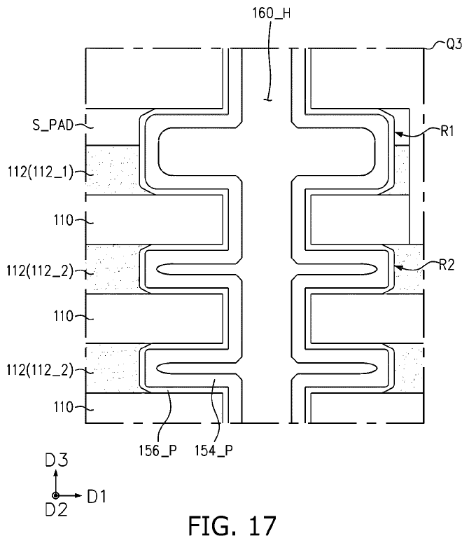

Referring to FIG. 17, a pre-liner insulating film 156_P and a pre-first insulating layer 154_P may be formed on the first through via hole 160_H, the first recess R1, and the second recess R2.

The pre-liner insulating film 156_P may extend along a profile of the first through via hole 160_H. In addition, the pre-liner insulating film 156_P may extend along the profile of the first recess R1 and the second recess R2. In some example embodiments, the pre-liner insulating film 156_P may be conformally formed.

The pre-first insulating layer 154_P may be formed on the pre-liner insulating film 156_P. The pre-first insulating layer 154_P may be formed along a profile of the pre-liner insulating film 156_P. The pre-first insulating layer 154_P may fill a portion of the first recess R1 and a portion of the second recess R2.

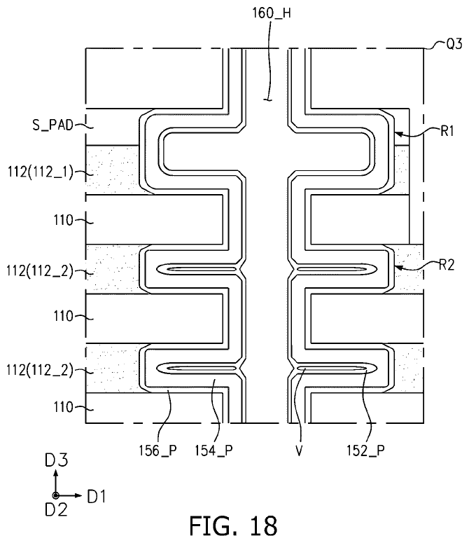

Referring to FIG. 18, a pre-second insulating layer 152_P may be formed on the pre-first insulating layer 154_P.

The pre-second insulating layer 152_P may extend along a profile of the pre-first insulating layer 154_P. The pre-second insulating layer 152_P may fill a portion of the first recess R1 and a portion of the second recess R2. In some example embodiments, a folding of the pre-second insulating layer 152_P may occur in the second recess R2 due to a relative height difference between the first recess R1 and the second recess R2. Accordingly, the void V may be formed in the pre-second insulating layer 152_P disposed on the second recess R2.

The pre-second insulating layer 152_P may include a material having etch selectivity with respect to the pre-first insulating layer 154_P. For example, the pre-second insulating layer 152_P may include silicon oxynitride or silicon nitride, and the pre-first insulating layer 154_P may include silicon oxide. However, example embodiments are not limited thereto.

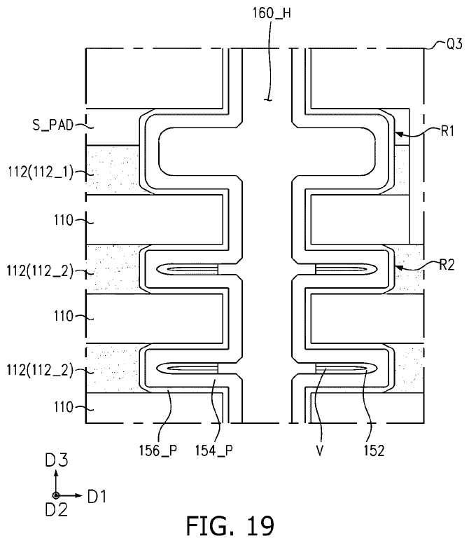

Referring to FIGS. 18 and 19, a portion of the pre-second insulating layer 152_P may be removed to form the first insulating layer 152.

Specifically, the pre-second insulating layer 152_P disposed on the first recess R1 may be entirely removed. On the other hand, a portion of the pre-second insulating layer 152_P disposed on the second recess R2 may be removed to form the first insulating layer 152. In some example embodiments, the void V may be exposed in the first insulating layer 152.

The process of removing a portion of the pre-second insulating layer 152_P may include a wet etching process using phosphoric acid, but example embodiments are not limited thereto.

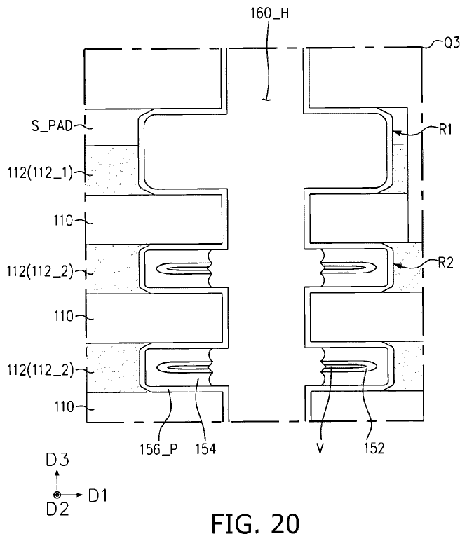

Referring to FIG. 20, a portion of a first pre-insulating layer 154_P may be removed to form the second insulating layer 154.

Specifically, the pre-first insulating layer 154_P disposed on the first recess R1 may be entirely removed. On the other hand, a portion of the pre-first insulating layer 154_P disposed on the second recess R2 may be removed to form the second insulating layer 154. In some example embodiments, when the first pre-insulating layer 154_P disposed on the second recess R2 is removed, a portion of the first insulating layer 152 may be removed.

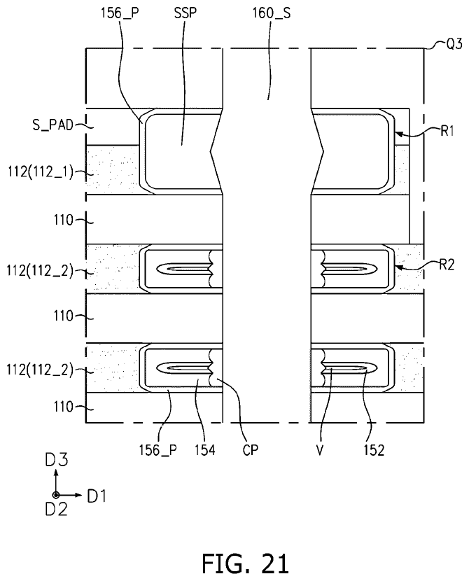

Referring to FIGS. 20 and 21, a sacrificial select pattern S_SP, a capping pattern CP, and a sacrificial through via 160_S may be formed on the first through via hole 160_H.

Specifically, an insulating material (e.g., silicon oxide or silicon oxynitride) may be formed on the pre-liner insulating film 156_P, the first insulating layer 152, and the second insulating layer 154. The insulating material may fill the remaining portions of the first recess R1 and the second recess R2. In addition, the insulating material may fill at least a portion of the first through via hole 160_H.

The insulating material may be removed by the etching process to form a sacrificial select pattern SSP disposed in the first recess R1 and a capping pattern CP disposed on the second recess R2. The capping pattern CP may cover the exposed portions of the first insulating layer 152 and the second insulating layer 154, for example, the side surfaces of the first insulating layer 152 and the second insulating layer 154. A portion of the pre-liner insulating film 156_P may be removed by a process of removing the insulating material.

The sacrificial through via 160_S may be formed in the first through via hole 160_H. Although the sacrificial through via 160_S is illustrated as a single layer, example embodiments are not limited thereto. For example, the sacrificial through via 160_S may include a plurality of films.

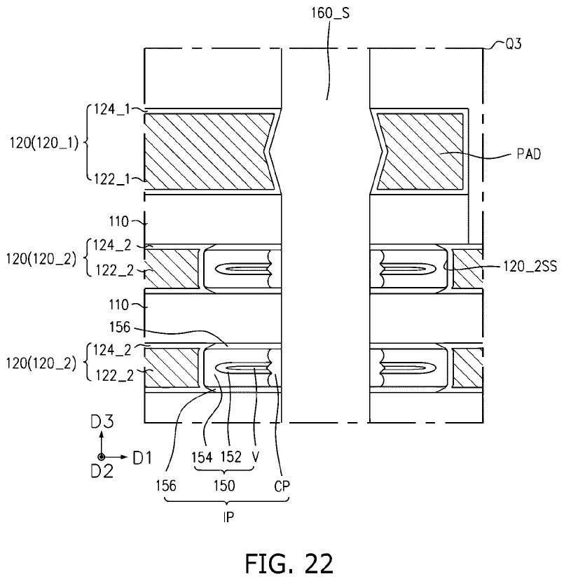

Referring to FIG. 22, the first mold sacrificial film 112, the pad sacrificial film S_PAD, and the pre-liner insulating film 156_P may be removed, and the gate electrode 120 may be formed.

Specifically, the select mold sacrificial film 112_1 and the pad sacrificial film S_PAD may be removed, and the first gate electrode 120_1 may be formed. In addition, the unselect mold sacrificial film 112_2 may be removed and the second gate electrode 120_2 may be formed.

The first gate electrode 120_1 may include the first filling conductive layer 122_1 and the first liner dielectric layer 124_1. The first liner dielectric layer 124_1 may surround the first filling conductive layer 122_1. The first liner dielectric layer 124_1 may be disposed on the through via 160_S that is exposed by removing the select mold sacrificial film 112_1 and the pad sacrificial film S_PAD.

When the unselect mold sacrificial film 112_2 is removed, the pre-liner insulating film 156_P disposed on a sidewall of the unselect mold sacrificial film 112_2 may be partially removed. For example, the pre-liner insulating film 156_P disposed on the sidewall of the unselect mold sacrificial film 112_2 may be removed to expose the second insulating layer 154 and form the liner insulating layer 156. The second gate electrode 120_2 may be formed. The second gate electrode 120_2 may include a second filling conductive layer 122_2 and a second liner dielectric layer 124_2.

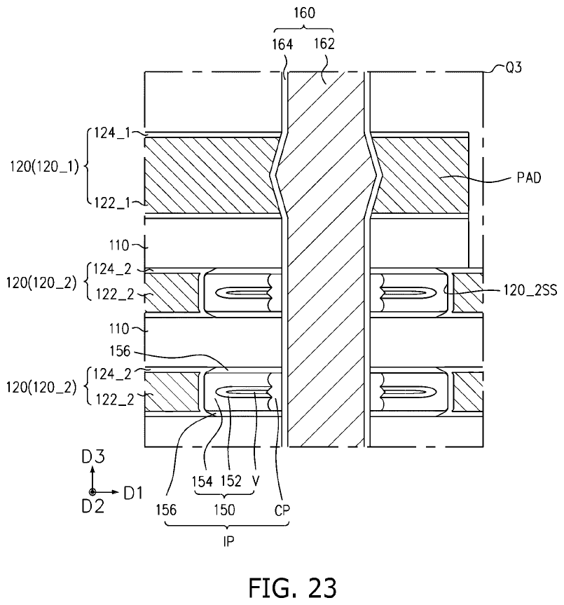

Referring to FIGS. 22 and 23, the sacrificial through via 160_S may be removed, and the first through via 160 may be formed. When the sacrificial through via 160_S is removed, the first liner dielectric layer 124_1 in contact with the sacrificial through via 160_S may be removed together. As a result, the first filling conductive layer 122_1 may be exposed. The barrier conductive film 164 and the conductive pillar 162 may be sequentially formed to form the first through via 160. Although not illustrated, the second through via (170 in FIG. 2) may be formed simultaneously with the first through via 160.

In the process of forming the first through via 160, if there is no capping pattern CP, a portion of the first through via 160 may be formed in the first insulating layer 152. For example, unlike the illustration, the barrier conductive film 164 may be formed on the void V disposed in the first insulating layer 152. In this case, the second gate electrode 120_2 may be electrically connected to the first through via 160, reducing reliability of the semiconductor memory device. On the other hand, in a semiconductor memory device according to some example embodiments, the capping pattern CP may be disposed on the first insulating layer 152 and the second insulating layer 154 to reduce and/or prevent penetration of the first through via 160. As a result, the second gate electrode 120_2 and the first through via 160 may be insulated, and electrical characteristics and/or reliability of the semiconductor memory device may be improved.

Referring to FIG. 2, the wiring contact 184 and the upper wiring structure 194 may be formed on the first through via 160 and the second through via 170. In addition, the bit line contact 182 and the bit line BL may be formed on the channel structure CH.

FIG. 24 is an example block diagram provided to explain an electronic system according to some example embodiments.

Referring to FIG. 24, an electronic system 1000 may include a semiconductor memory device 1100 described with reference to FIGS. 1 to 13, and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device, which may include one or the plurality of semiconductor memory devices 1100.

For example, the semiconductor memory device 1100 may be the NAND flash memory device described above with reference to FIGS. 1 to 13. The semiconductor memory device 1100 may include a first structure 1100F and a second structure 1100S on the first structure 1100F. The first structure 1100F may be a peripheral circuit structure including the decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor from among the plurality of memory cell transistors MCT. The decoder circuit 1110 and the page buffer 1120 may be controlled by the logic circuit 1130. The semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some example embodiments, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to desired (and/or alternatively predetermined) firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND controller interface 1221. The host interface 1230 may provide a communication function between the electronic system 1000 and an external host. Upon receiving a control command from the external host through the host interface 1230, the processor 1210 may control the semiconductor memory device 1100 in response to the control command.

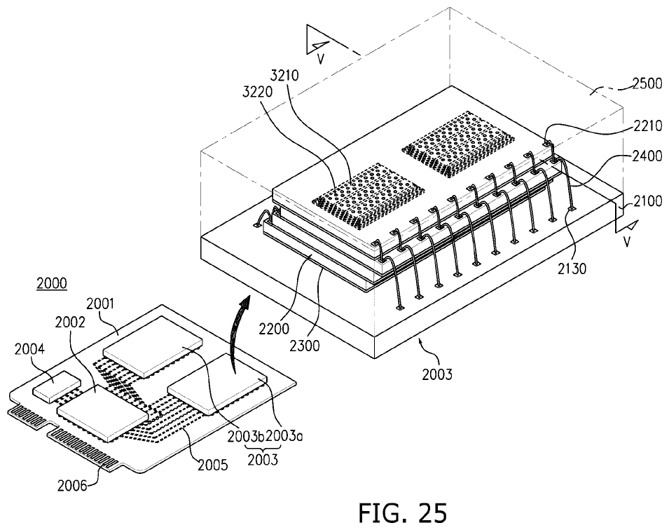

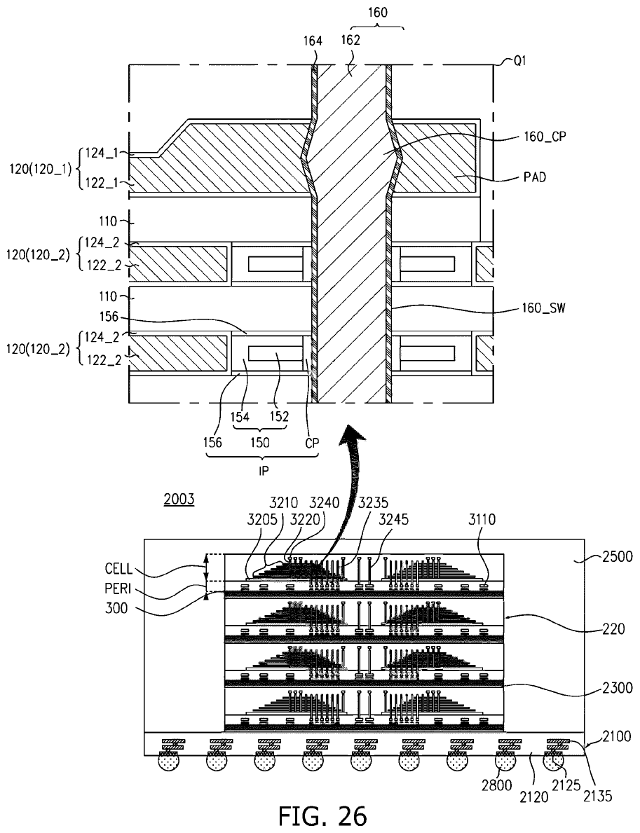

FIG. 25 is an example perspective view illustrating an electronic system 2000 including a semiconductor memory device according to some example embodiments. FIG. 26 is a schematic cross-sectional view taken along line V-V of FIG. 25.

Referring to FIGS. 25 and 26, the electronic system 2000 may include a main substrate 2001, a main controller 2002 mounted on the main substrate 2001, one or more semiconductor packages 2003, and a DRAM 2004. The semiconductor package 2003 and the DRAM 2004 may be connected to the main controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In some example embodiments, the electronic system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In some example embodiments, the electronic system 2000 may operate by the power supplied from the external host through the connector 2006. The electronic system 2000 may further include a Power Management Integrated Circuit (PMIC) that distributes the power supplied from the external host to the main controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 13. Each of the semiconductor chips 2200 may include gate stack structures 3210 and channel structures 3220. Each of the semiconductor chips 2200 may include the semiconductor memory device described above with reference to FIGS. 1 to 13.

In some example embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including Through Silicon Via (TSV) instead of a bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on an upper surface of the package substrate body portion 2120, lower pads 2125 disposed on a lower surface of the package substrate body portion 2120 or exposed through the lower surface, and internal wires 2135 electrically connecting the package upper pads 2130 and the lower pads 2125 inside the package substrate body portion 2120. The package upper pads 2130 may be electrically connected to the connection structures 2400. The lower pads 2125 may be connected to the wiring patterns 2005 of the main substrate 2001 of the electronic system 2000 through conductive connection portions 2800, as illustrated in FIG. 25.

In an electronic system according to some example embodiments, each of the semiconductor chips 2200 may include the semiconductor memory device described above with reference to FIGS. 1 to 13. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and a peripheral wiring 3110 described above with reference to FIGS. 1 to 13. In addition, for example, the cell structure CELL may include a common source line 3205, a gate stack structure 3210 on the common source line 3205, a channel structure 3220 and an isolation structure 3230 penetrating through the gate stack structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may be penetrating through the gate stack structure 3210 and may be further disposed outside the gate stack structure 3210. Each of the semiconductor chips 2200 may further include an input and output connection wiring 3265 electrically connected to the peripheral wiring 3110 of the peripheral circuit structure PERI and extending into a second structure 3200, and the input and output pad 2210 electrically connected to the input and output connection wiring 3265.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. Although certain example embodiments of the present disclosure have been described with reference to the accompanying drawings, those of ordinary skill in the art to which the present disclosure pertains will understand that the present disclosure may be implemented in other specific forms without changing the technical idea of the present disclosure or essential features. Therefore, it should be understood that the example embodiments described above are illustrative and non-limiting in all respects.

1. A semiconductor memory device, comprising:
a substrate including a cell array region and an extension region;
a plurality of gate electrodes alternately stacked in a first direction on the substrate and in a staircase structure on the extension region;
a channel structure penetrating through the plurality of gate electrodes on the cell array region and extending in the first direction;
a through via
penetrating through a first gate electrode of the plurality of gate electrodes and a second gate electrode of the plurality of gate electrodes, and
the second gate electrode being between the first gate electrode and the substrate;
the through via connecting to the first gate electrode; and
an insulating pattern between the second gate electrode and the through via, wherein
the insulating pattern includes
an insulating structure
on a sidewall of the second gate electrode,
the insulating structure including a first insulating layer and a second insulating layer surrounding the first insulating layer, and
the insulating structure in contact with upper and lower surfaces of the first insulating layer, and
a capping pattern between the insulating structure and the through via.

2. The semiconductor memory device according to claim 1, wherein the capping pattern is in contact with the first insulating layer and the second insulating layer, respectively.

3. The semiconductor memory device according to claim 1, wherein
the insulating pattern further includes a liner insulating layer on an upper surface of the insulating structure,
the liner insulating layer extends in a second direction, the second direction different from the first direction, and
the liner insulating layer covers an upper surface of the capping pattern.

4. The semiconductor memory device according to claim 1, wherein the capping pattern is in contact with the sidewall of the through via.

5. The semiconductor memory device according to claim 1, wherein
the capping pattern includes a first capping layer and a second capping layer,
the first capping layer is on the insulating structure,
the second capping layer is between the first capping layer and the through via, and
the first capping layer includes a material different from a material of the second capping layer.

6. The semiconductor memory device according to claim 1, wherein
the first gate electrode includes a first filling conductive layer and a first liner dielectric layer surrounding the first filling conductive layer, and
the first filling conductive layer is in contact with the through via.

7. The semiconductor memory device according to claim 1, wherein
the second gate electrode includes a second filling conductive layer and a second liner dielectric layer surrounding the second filling conductive layer, and
the second liner dielectric layer is in contact with the second insulating layer.

8. The semiconductor memory device according to claim 1, wherein the insulating structure further includes a void in the first insulating layer.

9. The semiconductor memory device according to claim 8, wherein the capping pattern and the first insulating layer surround the void.

10. The semiconductor memory device according to claim 1, wherein the capping pattern includes a protrusion portion protruding toward the second insulating layer.

11. The semiconductor memory device according to claim 1, wherein the capping pattern includes a wedge pattern on the first insulating layer.

12. The semiconductor memory device according to claim 1, wherein
the through via includes a conductive pillar extending in the first direction and a barrier conductive film surrounding the conductive pillar, and
the conductive pillar includes a connection portion protruding toward the first gate electrode.

13. The semiconductor memory device according to claim 1, wherein the sidewall of the second gate electrode has a concave shape.

14. A semiconductor memory device, comprising:
a substrate including a cell array region and an extension region;
a mold structure including a plurality of gate electrodes and a plurality of mold insulating layers alternately stacked on a first side of the substrate in a first direction, the first direction being perpendicular to the first side of the substrate;
the mold structure including the plurality of gate electrodes with a pad portion in a staircase structure on the extension region;
a channel structure penetrating through the plurality of gate electrodes and extending on the cell array region in the first direction;
a through via
penetrating through a pad portion of a first gate electrode of the plurality of gate electrodes and a second gate electrode of the plurality of gate electrodes on the extension region,
the second gate electrode being between the first gate electrode and the substrate, and
the second gate electrode electrically connected to the pad portion of the first gate electrode; and
an insulating pattern between the second gate electrode and the through via and surrounding a portion of a sidewall of the through via,
wherein
the insulating pattern includes
an insulating structure including a first insulating layer and a second insulating layer surrounding three surfaces of the first insulating layer,
a capping pattern between the insulating structure and the through via, and
the capping pattern covers a first side of the insulating structure defined by a side surface of the first insulating layer and a side surface of the second insulating layer.

15. The semiconductor memory device according to claim 14, wherein
the insulating structure includes a first side and a second side facing the first side in a second direction, the second direction being different from the first direction, and
the second side of the insulating structure is in contact with the second gate electrode.

16. The semiconductor memory device according to claim 14, wherein
the insulating pattern further includes
a mold insulating layer of the plurality of mold insulating layers, the mold insulating layer being on the second gate electrode, and
a liner insulating layer between the insulating structure and extending in a second direction, the second direction being different from the first direction.

17. The semiconductor memory device according to claim 14, wherein a thickness of the pad portion of the first gate electrode is greater than a thickness of a plate of the first gate electrode.

18. The semiconductor memory device according to claim 14, wherein
the capping pattern includes
a wedge pattern on the first insulating layer, and
a protrusion portion protruding toward the second insulating layer.

19. The semiconductor memory device according to claim 14, further comprising:
a peripheral circuit structure on a second side facing the first side of the substrate,
wherein the through via is penetrating through the substrate and connected to the peripheral circuit structure.

20. An electronic system, comprising:
a main substrate;
a semiconductor memory device on the main substrate;
the semiconductor memory device including a peripheral circuit structure, and a cell structure stacked on the peripheral circuit structure; and
a controller on the main substrate, the controller being electrically connected to the semiconductor memory device,
wherein the cell structure includes
a substrate including a cell array region and an extension region,
a plurality of gate electrodes alternately stacked on the substrate in a first direction, and in a staircase structure on the extension region,
a channel structure penetrating through the plurality of gate electrodes on the cell array region and extending in the first direction,
a through via
penetrating through a first gate electrode of the plurality of gate electrodes and a second gate electrode of the plurality of gate electrodes, and
the second gate electrode being between the first gate electrode and the substrate,
the through via connecting to the first gate electrode,
an insulating pattern between the second gate electrode and a sidewall of the through via, and
the through via is penetrating through the substrate and connected to the peripheral circuit structure, and
the insulating pattern includes
an insulating structure on a sidewall of the second gate electrode, and
the insulating structure including
a first insulating layer and a second insulating layer, and
the second insulating layer surrounding the first insulating layer and in contact with upper and lower surfaces of the first insulating layer, and a capping pattern between the insulating structure and the through via.
